(19) United States
(12) Patent Application Publication
(10) Pub. No.: US 2023/0019587 A1
(43) Pub. Date: Jan. 19, 2023

(54) SEMICONDUCTOR PHOTODIODE

(71) Applicant: ROCKLEY PHOTONICS LIMITED, Altrincham (GB)

(72) Inventors: Guomin YU, Glendora, CA (US); Henri NYKÄNEN, Helsinki (FI); Evie KHO, Espoo (FI)

(21) Appl. No.: 17/862,338

(22) Filed: Jul. 11, 2022

(30) Foreign Application Priority Data
Jul. 12, 2021 (GB) 2110040.9

(51) Int. Cl. H01L 31/105; H01L 31/0224; H01L 31/0352; H01L 31/18; G02B 6/42

(52) U.S. Cl. CPC H01L 31/105; H01L 31/022408; H01L 31/035281; H01L 31/03529; H01L 31/1808; G02B 6/42; G02B 6/4275

(57) ABSTRACT

A semiconductor photodiode. The semiconductor photodiode including: an input waveguide, arranged to receive an optical signal at a first port and provide the optical signal from the second port; a photodiode waveguide, arranged to receive the optical signal from the second port of the input waveguide, and at least partially convert the optical signal into an electrical signal; and an electro-static defence component, located adjacent to the photodiode waveguide. The electro-static defence component and the photodiode waveguide are electrically connected in parallel.

### CROSS-REFERENCE TO RELATED APPLICATION(S)

This application claims priority to United Kingdom Patent Application No. 2110040.9, filed in the United Kingdom Intellectual Property Office on Jul. 12, 2021, which is incorporated by reference herein in its entirety.

### FIELD OF THE INVENTION

The present invention relates to a semiconductor photodiode.

### BACKGROUND

Photodiodes are semiconductor devices which convert an optical signal into an electrical signal. When applies in a photonics context, a photodiode will often be implemented in waveguide form. Light is directed into one end of a waveguide which has been adapted to operate as a photodiode (e.g. through inclusion of one or more optically active layers). The light is then converted into a photocurrent and read off via one or more electrodes.

When integrating waveguide photodiodes into a photonic integrated circuit, or similar, it is desirous that the device is protected from electrostatic discharge, or ESD. Electrostatic discharge is the sudden flow of electricity through the device. For example, it is desirous that devices for inclusion in commercial products be able to withstand an ESD in excess of 200 V.

However, at the same time, it is important that when improving the resilient of the photodiodes to ESD events, their core performance characteristics (e.g. responsivity, bandwidth, dark current, etc.) are not adversely affected.

### SUMMARY

The present inventors have identified that a root cause of failure to pass an ESD test in a semiconductor photodiodes is that the current density is very high at the interface area between a photodiode waveguide slab and the electrode (shown in the circled areas of FIG. 2A).

Accordingly, in a first aspect, embodiments of the present invention provide a semiconductor photodiode, the semiconductor photodiode including:
an input waveguide, arranged to receive an optical signal at a first port and provide the optical signal from the second port;
a photodiode waveguide, arranged to receive the optical signal from the second port of the input waveguide, and at least partially convert the optical signal into an electrical signal; and
an electro-static defence component, located adjacent to the photodiode waveguide;
wherein the electro-static defence component and the waveguide photodiode are electrically connected in parallel.

Advantageously, such a semiconductor photodiode displays enhanced ESD characteristics whilst maintaining the core performance characteristics.

The photodiode waveguide may be optically coupled to the electro-static defence (ESD) component such that light can be conveyed from the photodiode waveguide to the ESD component. This may be a direct coupling from one component to another, or may be indirect optical coupling from the photodiode to the ESD via another optical component.

The electro-static defence component can provide a large bias voltage and large sectional area which substantially enhances the ESD test performance of a semiconductor photodiode whilst not impairing the core performance characteristics (for example bandwidth, or speed).

By connecting in parallel, it may be meant that the semiconductor photodiode includes an output pair of electrodes which are configured to relay the electrical signal out of the semiconductor photodiode, and that the electro-static defence component and waveguide photodiode are electrically connected in parallel relative to the output pair of electrodes.

The photodiode waveguide and electro-static defence component may be electrically connected via a pair of electrodes. Each electrode may have a wider cross-section in a region adjacent to the electro-static defence component than a region adjacent to the photodiode waveguide.

The photodiode waveguide and electro-static defence component may be electrically connected via a pair of doped regions of semiconductor. Each doped region of semiconductor may have a wider cross-section in a portion adjacent to the electro-static defence component than a portion adjacent to the photodiode waveguide.

The photodiode waveguide may include first and second doped regions which extend from a slab adjacent to the waveguide along respective sidewalls of the waveguide. The first and second doped regions of the photodiode waveguide may each contain a first and second sub-region, the first sub-region of each doped region containing a higher concentration of dopants than the second sub-region of each doped region. The first sub-regions of the first and second doped regions of the photodiode waveguide may extend only along the slab adjacent to the waveguide.

The electro-static defence component may include first and second doped regions extending from the slab adjacent to the photodiode waveguide up respective sidewalls of a waveguide within the electro-static defence component, which is coupled to the photodiode waveguide.

The first and second doped regions of the electro-static defence component may each contain a first and second sub-region. The first sub-region of each doped region may contain a higher concentration of dopants than the second sub-region of each doped region. The first and second sub-regions of the first and second doped regions of the electro-static defence component may extend along a slab and also up respective sidewalls of the waveguide within the electro-static defence component.

The photodiode waveguide and the electro-static defence component may each contain a P-I-N junction. A width of the intrinsic region of the P-I-N junction within the electro-static defence component may be smaller than a corresponding width of the intrinsic region of the P-I-N junction within the photodiode waveguide.

The electro-static defence component may be wider than the photodiode waveguide. The width may be measured perpendicular to a guiding direction of the photodiode waveguide. The photodiode waveguide may include a tapered region, which may taper from a width of the photodiode waveguide to the width of the electro-static defence component. The electro-static defence component and the photodiode waveguide may each comprise a doped region, and the doped region of the electro-static defence component may be further from a substrate of the semiconductor photodiode than the doped region of the photodiode waveguide.

The semiconductor photodiode may further comprise a substrate, a device layer, and an insulator layer located between the substrate and the device layer. The photodiode waveguide and electro-static defence component may be each located on a same opposing side of the device layer to the insulator layer. The insulator layer may be a buried oxide layer, for example silicon dioxide (SiO₂).

The semiconductor photodiode may further comprise a substrate, a device layer, and a semiconductor seed layer located between the substrate and the device layer. The photodiode waveguide and electro-static defence component may be each located on a same opposing side of the device layer to the semiconductor seed layer. The semiconductor seed layer may be an epitaxial crystalline layer. The semiconductor photodiode may further comprise an insulator layer located on one or more lateral sides of the semiconductor seed layer. By lateral sides, it may be meant ones which are within a plane of the substrate.

### BRIEF DESCRIPTION OF THE DRAWINGS

Embodiments of the invention will now be described by way of example with reference to the accompanying drawings in which:

FIG. 1 shows a top-down view of a semiconductor photodiode;

FIGS. 2A and 2B show cross-sectional views of the semiconductor photodiode of FIG. 1 along the lines A-A′ and B-B′ respectively;

FIGS. 3(i)(A)-(ix)(B) show various manufacturing steps along the lines A-A′ and B-B′ respectively;

FIG. 4 shows a top-down view of a variant semiconductor photodiode;

FIGS. 5A and 5B show cross-sectional views of the variant semiconductor photodiode of FIG. 4 along the lines A-A′ and B-B′ respectively;

FIGS. 6A and 6B show cross-sectional views of a variant of the semiconductor photodiode of FIG. 1 along the lines A-A′ and B-B′ respectively;

FIGS. 7A and 7B show cross-sectional views of a variant of the semiconductor photodiode of FIG. 4 along the lines A-A′ and B-B′ respectively;

FIG. 8 shows a top-down view of a simulated variant semiconductor photodiode; and

FIGS. 9A and 9B show cross-sectional views of the variant semiconductor photodiode of FIG. 8 along the lines A-A′ and B-B′ respectively.

### DETAILED DESCRIPTION AND FURTHER OPTIONAL FEATURES

Aspects and embodiments of the present invention will now be discussed with reference to the accompanying figures. Further aspects and embodiments will be apparent to those skilled in the art.

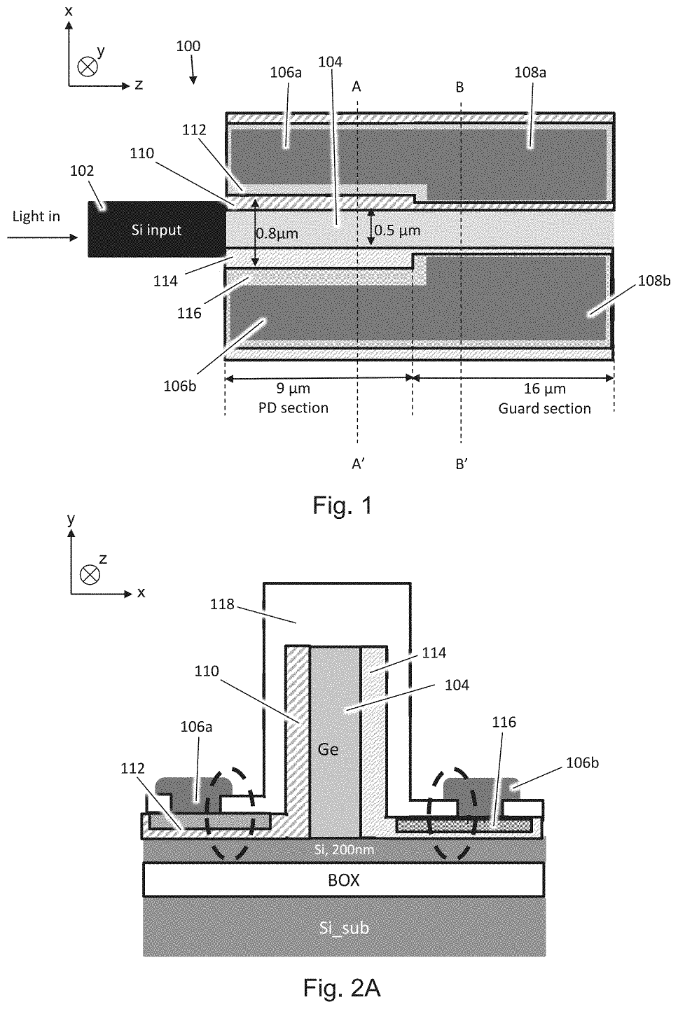

FIG. 1 shows a top-down view of a semiconductor photodiode 100. The semiconductor photodiode includes an input waveguide 102, in this example formed of silicon, which receives light into an input port or facet. The light is conveyed to an output port or facet, which is adjacent to a photodiode waveguide section, or PD section. The semiconductor photodiode also includes an electro-static defence component or guard section. The PD section may be optically coupled to the guard section. The semiconductor photodiode 100 includes a germanium waveguide 104. In other examples the waveguide may be formed of silicon germanium (SiGe). A first portion of the waveguide, corresponding to the PD section, includes an n doped region 110 and an N++ doped region 112 located on a first side of the waveguide. On an opposing side of the waveguide is P doped region 114 and P++ doped region 116. Photodiode electrodes 106a and 106b connected, respectively, to the N++ and P++ doped regions.

The photodiode electrodes 106a and 106b are connected in parallel with metal contacts 108a and 108b respectively. These metal contacts form a part of the electro-static defence component or guard section. Therefore, in this example, the electro-static defence component comprises a first and second metal contact which are respectively connected in parallel to electrodes 106a and 106b.

In this example, the photodiode section (i.e. the section in which the majority of conversion to photocurrent is to take place) is around 9 μm long as measured in the z direction from the output facet of the silicon waveguide 102 to the beginning of the guard section. The z direction is generally parallel to the guiding direction of the silicon or germanium waveguides. A length of around 9 μm allows >99.9% of light with a wavelength of 1310 nm to be absorbed. The guard section is around 16 μm long, as measured from an end of the photodiode section to an end of the semiconductor photodiode 100.

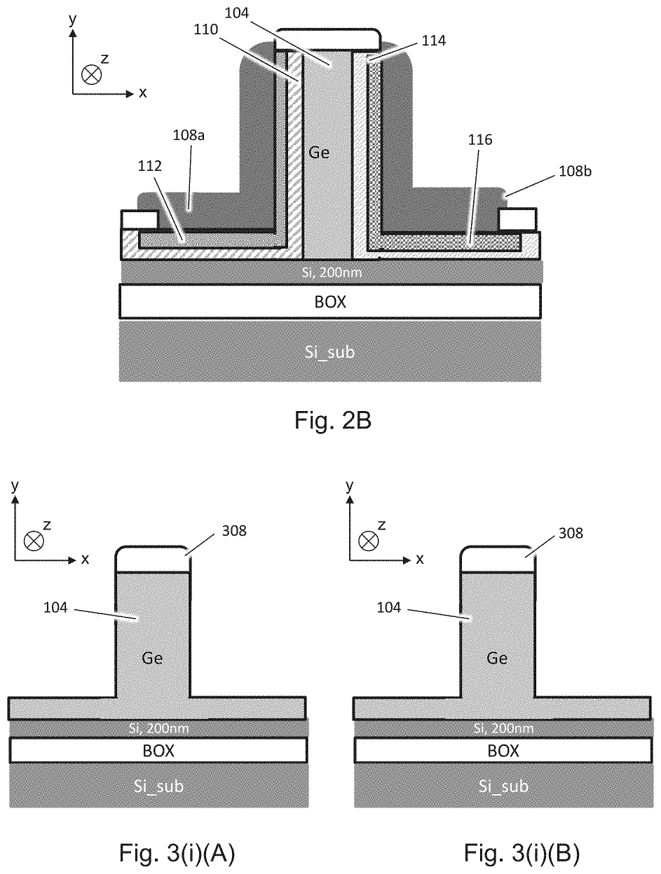

FIGS. 2A and 2B show cross-sectional views of the semiconductor photodiode of FIG. 1 along the lines A-A′ and B-B′ respectively. As can be seen, the height and width of the waveguide sections in both the PD section and guard section are the same. In this example the waveguide 104 undoped region (or I-region, shown as solid in FIG. 2A) is around 0.5 μm wide, with a waveguide width (a distance from the left edge of N dope region 110 to the right edge of P dope region 114 in FIG. 2A) of around 0.8 μm. FIG. 2A corresponds to a cross-sectional view through the PD section of the photodiode 100. As can be seen, the N doped region 110 and P doped region 114 extend along a slab of the waveguide and then up respective sidewalls of the waveguide 104. Whereas the N++ doped region 112 and P++ doped region 116 are confined to the slab portion only. In contrast, in FIG. 2B (corresponding to a cross-sectional view through the guard section) the N++ doped region 112 and P++ doped region 116 also extend up respective sidewalls of the waveguide 104. However, the depth of these heavily doped regions is shallow than those of the more lightly doped regions. That is, an outermost region of the waveguide is more heavily doped than an inner region of the waveguide.

Further, as can be seen in FIG. 2A, photodiode electrodes 106a and 106b extend through an upper cladding layer 118 to electrically contact their respective heavily doped regions. In contrast, and as shown in FIG. 2B, the metal contacts 108a and 108b extend both along an upper surface of the slab and also along the lateral surfaces of the sidewall of the waveguide (and so are in electrical contact with the entirety of their respective heavily doped region). Notably, in this example, the PD section and guard section have the same PIN junction structure and so have the same breakdown voltage.

As was discussed previously, the inventors have identified that a root cause of failure in ESD testing is that the current density is too high at the interface area between the photodiode waveguide slab and the electrodes (shown as the circled areas in FIG. 2A). The inventors have experimentally verified that decreasing the current density in this area increases the photodiode's failure voltage during an ESD test. The guard section lowers the current density in this area through two functions: (i) it has lower series resistance than the photodiode section, so the junction of the guard section has a larger bias voltage, and breaks down before the photodiode section, to ensure that the majority of the short current goes through the guard section; and (ii) it provides a large area in contact with the doped regions to ensure that the current density is low enough to withstand the ESD required voltages without failure.

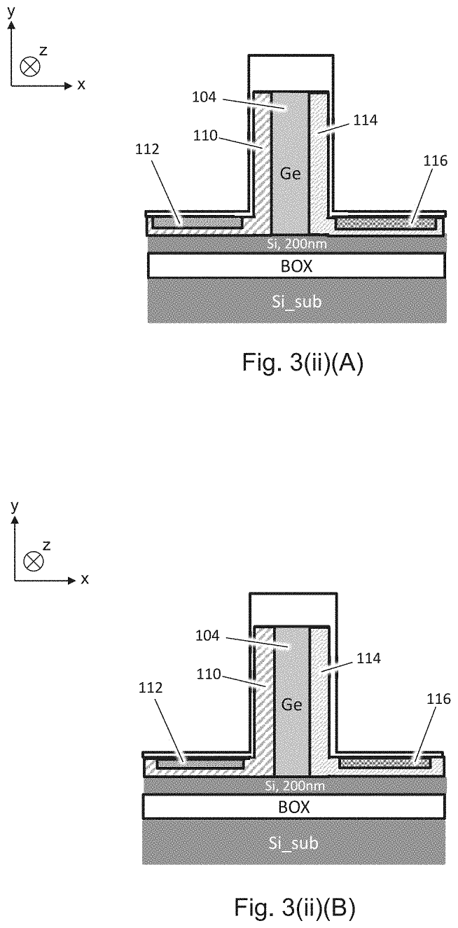

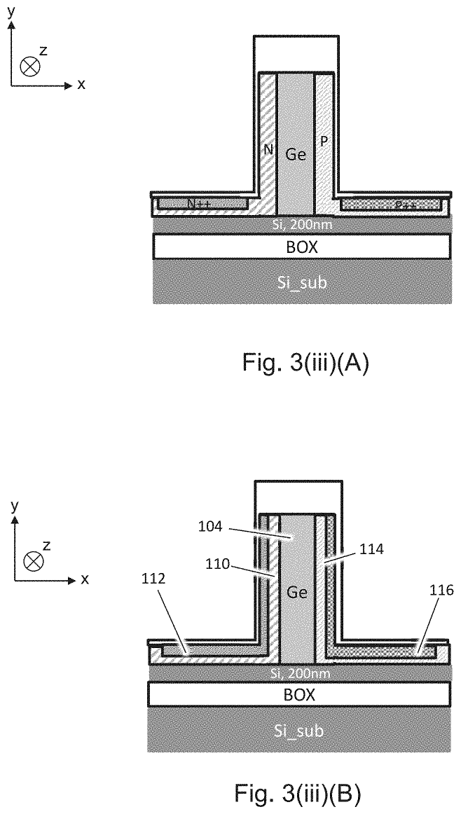

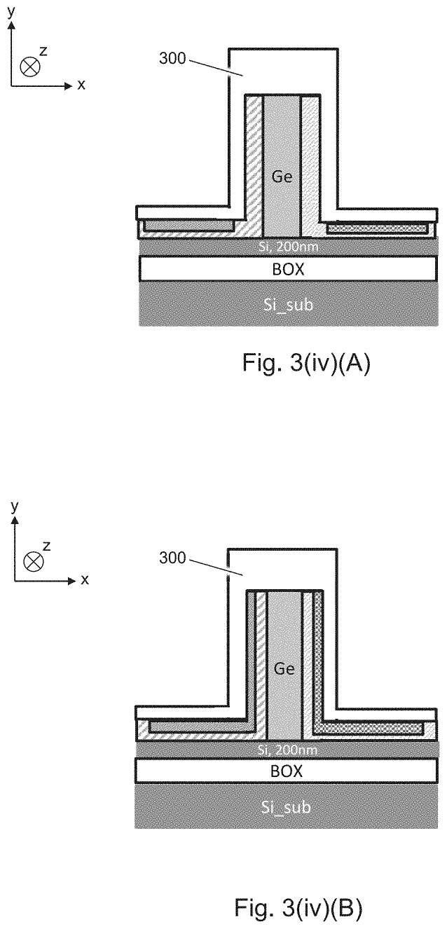

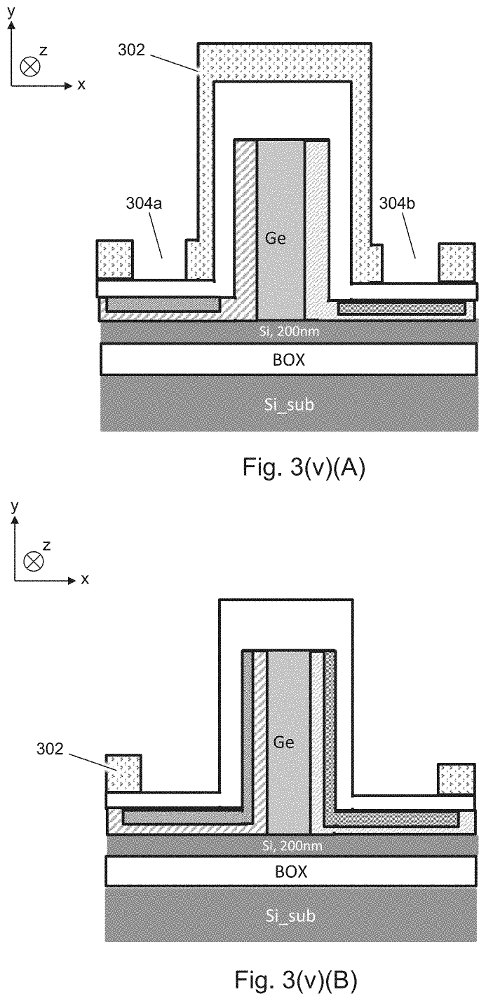

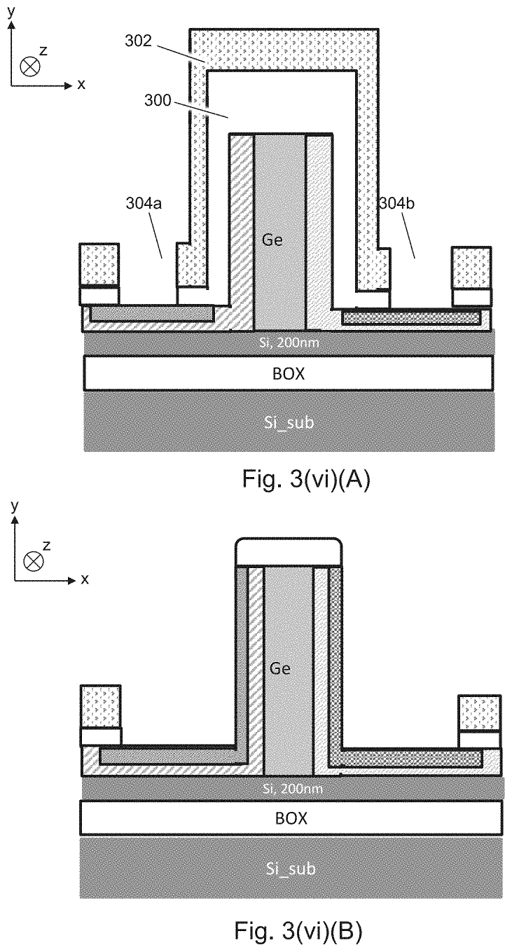

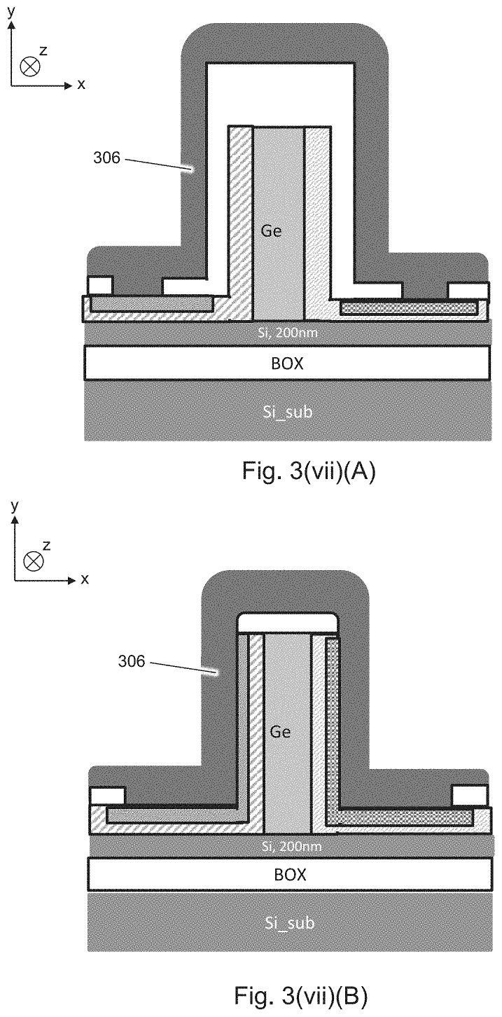

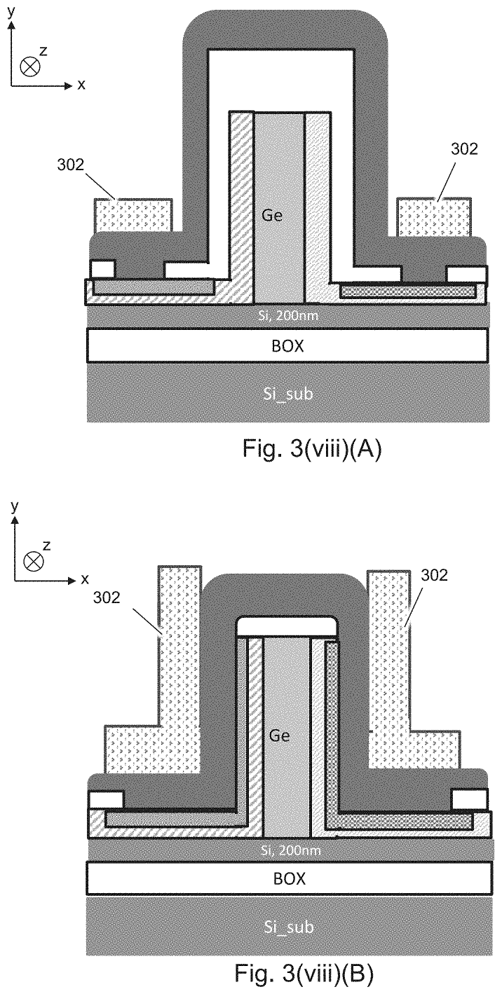

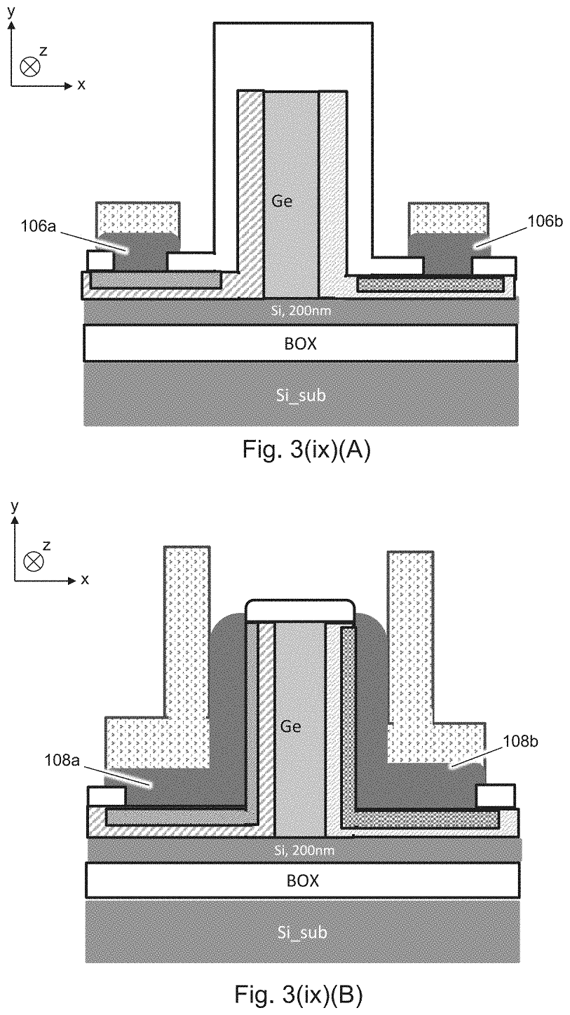

FIGS. 3(i)(A)-3(ix)(B) show various manufacturing steps along the lines A-A′ and B-B′ respectively. In a first step shown in FIGS. 3(i)(A) and 3(i)(B), germanium waveguides 104 are provided which are topped by a hard mask 308 (formed of silicon dioxide in this example). Next, a dopant screen is deposited to allow N and P doping with a dopant concentration 0.5-5×10¹⁸ cm⁻³. In one example, the screen is an ion implantation screen oxide with thickness of 30-50 nm, and the dopants are N and P type (phosphorus and Boron) ions. The N and P type doping dopes both the slab and the waveguide sidewalls. After this, N++ and P++ with a dopant concentration 0.5-20×10¹⁹ cm⁻³ doping is performed on just the slabs. The result of this is shown in FIGS. 3(ii)(A) and 3(ii)(B). Next, in a step the result of which is shown in FIGS. 3(iii)(A) and (B), further N++ and P++ doping is performed on the sidewalls of the guard section (shown in FIG. 3(iii)(B)). The doping thicknesses of the N++ and P++ regions are less than their respective N and P doped regions.

The structure is then annealed at 600-650° C. for 5-30 sec and insulator 300 (in this example silicon dioxide) is deposited over the exposed surfaces. This is shown in FIGS. 3(iv)(A) and (B). Next, a photoresist 302 is deposited and defined through lithography. The result of this is shown in FIGS. 3(v)(A) and (B), where vias 304a and 304b in the PD section extend expose a portion of the insulator above the heavily doped regions. In contrast, the lithography of the photoresist 302 in the guard section ensures that the majority of the structure is exposed i.e. all of the heavily doped regions and the upper portion of the waveguide. An etch is then performed to remove the exposed insulator, as shown in FIGS. 3(vi)(A) and (B). In the PD section, shown in FIG. 3(vi)(A), this means that the heavily doped regions are now exposed through vias 304a and 304b. In the guard section, shown in FIG. 3(vi)(B), all of the insulator adjacent to the portions of the sidewalls and slab containing heavily doped regions are removed. The etch can be a two-step etch with an initial isotropic dry etch to around 100 nm, and then a wet etch performed after. The hard mask is retained above the waveguide, as shown in FIG. 3(vi)(B).

Next, the photoresist is stripped and metal 306 deposited over the exposed surfaces. This is shown in FIGS. 3(vii)(A) and (B). The metal is deposited to a thickness of at least around 1 μm and no more than around 1.2 μm. Further photoresist 302 is deposited and patterned with the result shown in FIGS. 3(viii)(A) and (B). As can be seen, in the photodiode section the metal extending up the sidewalls of the waveguide and across the top of the waveguide is exposed. Whereas in the guard section only the metal across the top of the waveguide is exposed. One or more etches are then performed to remove the exposed metal. The result of this is shown in FIGS. 3(ix)(A) and (B). The etch may be a dry etch, or a wet etch, or both in a cascade. The photoresist is then stripped in a final step, resulting in the structure shown in FIGS. 2(A) and 2(B).

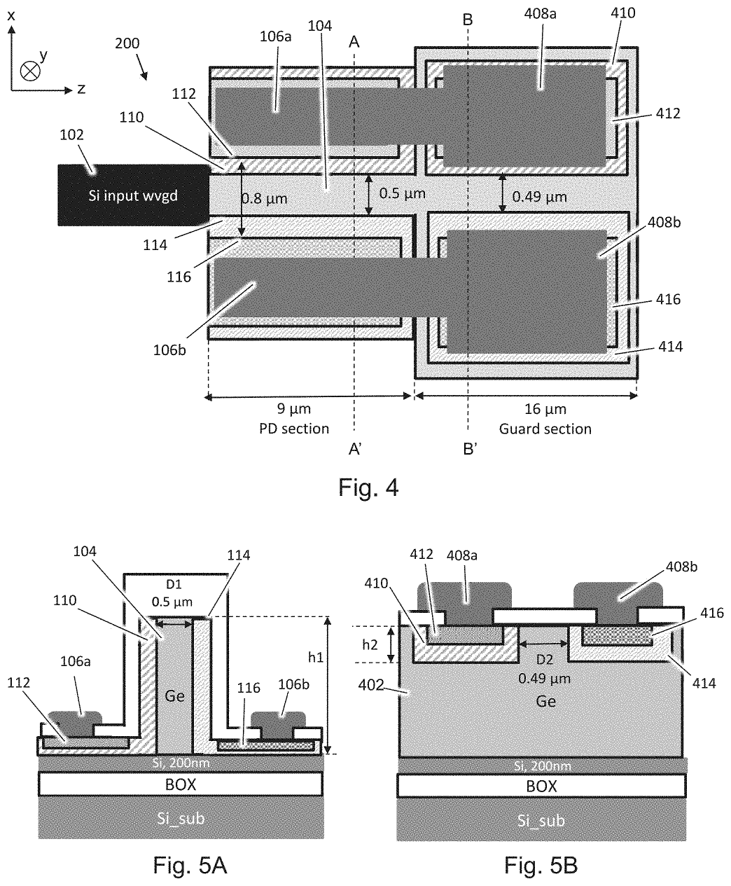

FIG. 4 shows a top-down view of a variant semiconductor photodiode 200. Where the variant semiconductor photodiode 200 shares features with the semiconductor photodiode 100 shown in FIG. 1, like features are indicated by like reference numerals. The photodiode section in both semiconductor 100 and 200 are the same. However the guard section has no waveguide in semiconductor photodiode 200, and is instead provided by bulk semiconductor 402 (e.g. germanium or silicon germanium). This is shown most clearly in FIGS. 5A and 5B which are cross-sectional views of the variant semiconductor photodiode of FIG. 4 along the lines A-A′ and B-B′ respectively. As can be seen, the N 110, N++ 112, P 114, and P++ 116 doped regions of the photodiode section are the same as shown previously. However these doped sections in the guard section in FIG. 5B are arranged differently. Metal contacts 408a and 408b extend through a via to contact an upper surface of the bulk semiconductor, and respectively electrically connect to an N++ doped region 412 and a P++ doped region 416 which are formed in the upper surface of the bulk semiconductor. Surrounding the heavily doped regions are ‘U’ shaped lightly doped regions: N doped region 410 and P doped region 414. As the depth of the N doped region 410 and P doped region 414 (dimension h2) is less than the corresponding distance (h1) in the photodiode section, the capacitance is smaller in the guard section than the photodiode section. Further, the width of the intrinsic region between the N doped region 410 and P doped region 414 is less than the corresponding intrinsic region width between N doped region 110 and P doped region 114. In this example, the intrinsic region width (D2) in the guard section is around 0.49 μm whereas the intrinsic region width (D1) in the photodiode section is 0.5 μm. This can help to ensure that the guard section breaks down first during reverse bias operation, and so protects the photodiode section. In contrast to the semiconductor photodiode 100 of FIG. 1, the contact area is significantly larger in the guard section which reduces the contact resistance. Further, since the device's bandwidth is dominated by its capacitive reactance, the device demonstrates an enhanced bandwidth as compared to example shown in FIG. 1.

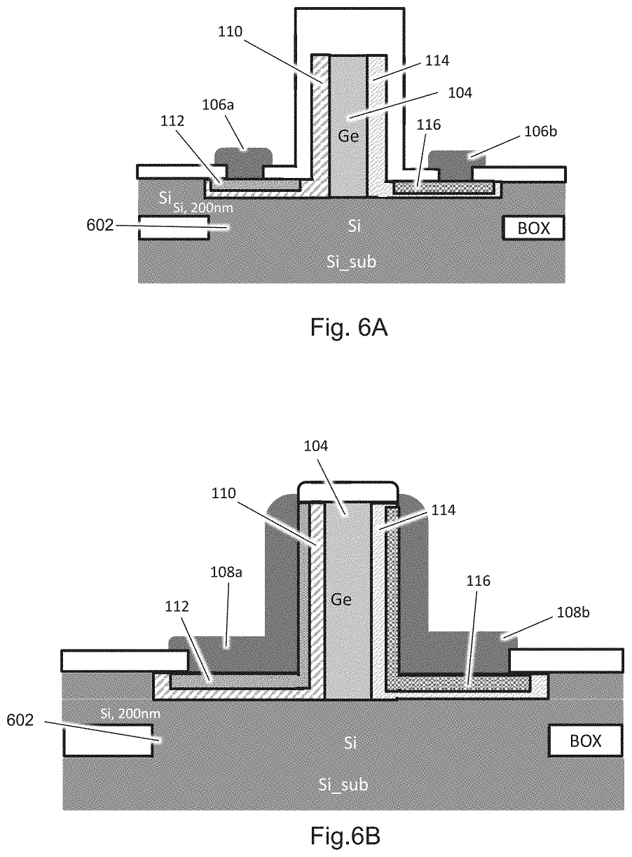

FIGS. 6A and 6B show cross-sectional views of a variant of the semiconductor photodiode of FIG. 1 along the lines A-A′ and B-B′ respectively. Where the variant semiconductor photodiode shares features with the semiconductor photodiode 100 shown in FIG. 1, like features are indicated by like reference numerals. The semiconductor photodiode shown in FIGS. 6A and 6B differs in that the buried oxide layer below the germanium waveguide 104 is removed and a semiconductor seed layer 602 is grown instead. In this example, the semiconductor seed layer is a regrown silicon layer which may be an epitaxial crystalline layer.

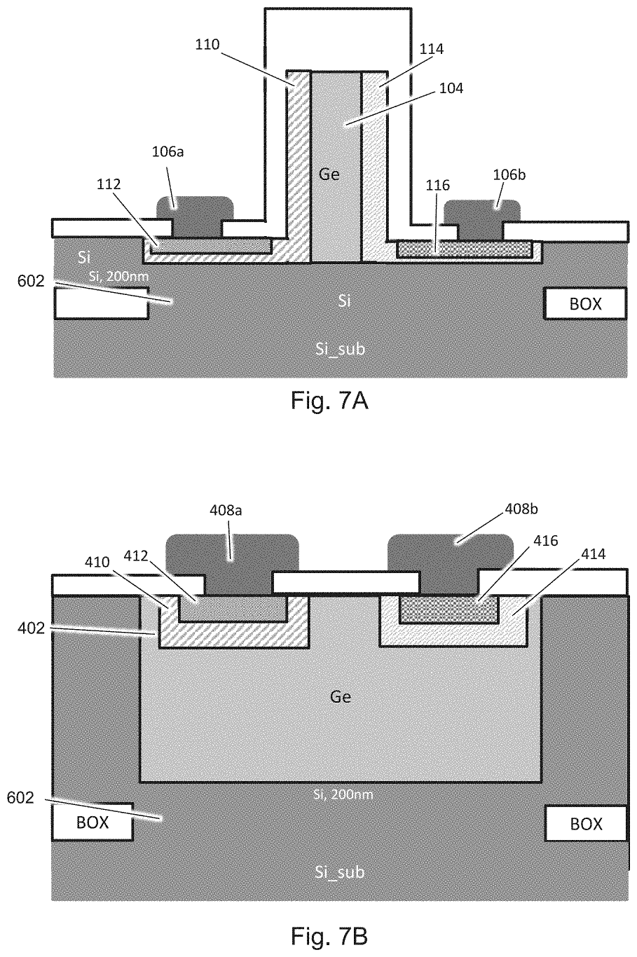

FIGS. 7A and 7B show cross-sectional views of a variant of the semiconductor photodiode of FIG. 4 along the lines A-A′ and B-B′ respectively. Where the variant semiconductor photodiode shares features with the semiconductor photodiode 200 shown in FIG. 4, like features are indicated by like reference numerals. The semiconductor photodiode shown in FIGS. 7A and 7B differs in that the buried oxide layer below the germanium waveguide 104 is removed and a semiconductor seed layer 602 is grown instead. In this example, the semiconductor seed layer is a regrown silicon layer which may be an epitaxial crystalline layer.

The semiconductor photodiode of FIGS. 1 and 2A and 2B was simulated, where the slab was around 250 nm thick, and the silicon device layer was around 200 nm thick. The results of the simulation indicated that, for light at 1310 nm, >99.99% of the optical signal was absorbed within the first 9 μm of the germanium waveguide. Less than 0.01% of the original signal enters the 16 μm guard section, and therefore the heavy doping on the sidewalls does not degrade either the responsivity or the speed of the semiconductor photodiode. However the guard section does increase the contact area and so enhances the ESD performance of the device. Table 1 shows a comparison between a semiconductor photodiode not employing the electro-static defence component and one which does:

TABLE 1

| | Effective | | | | |
|---|---|---|---|---|---|
| | length | | Min. | | ESD |
| | (μm) of | | Current | | Volt/ |
| | the heavily | Slab | Section | ESD | area |
| | doped | thick- | Area | Voltage | (V/ |
| Design | regions | ness | (μm²) | (V) | μm²) |
| Photodiode | 15 | 0.25 | 3.75 | 60 | 16.00 |
| without | 26 | 0.25 | 6.5 | 100 | 15.38 |
| electro- | 50 | 0.25 | 12.5 | 200 | 16.00 |
| static | | | | | |
| defence | | | | | |
| component | | | | | |
| Photodiode | Photodiode | 0.25 | 2.25 | Protected | |
| with | section 9 | | | by | |
| electro- | | | | guard | |
| static | | | | section | |
| defence | Guard | 2.8 | 44.8 | 224 | 5.00 |
| component | section 16 | | | | |
| provided | Total 25 | | 44.8 | 224 | 5.00 |

Compared to a photodiode with length of 26 μm without an electro-static defence component, the ESD voltage of a photodiode with length of 25 μm having the electro-static defence component is extended to 224V from 100V even with almost one third of the ESD voltage per micron square of min current section area (5 V/μm² Vs 15.38 V/μm²). With the same ESD voltage per micron square of 15.38V/μm², the ESD voltage of the photodiode with length of 25 μm having the electro-static defence component can be extended to 689V. In other words, a photodiode with a length of 25 μm and having the electro-static defence component will have an ESD voltage more of than 200 V, with significant margin.

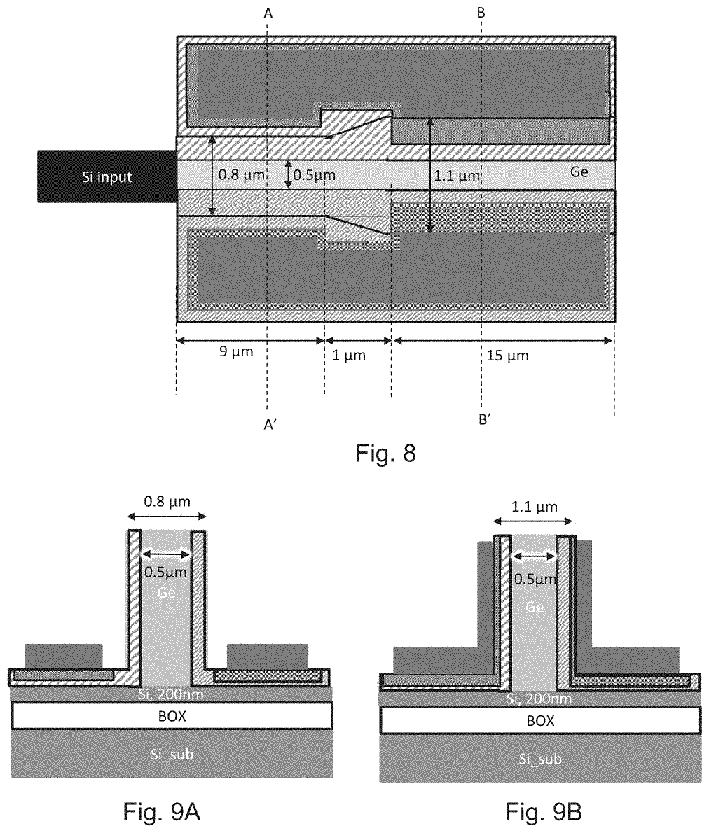

FIG. 8 shows a top-down view of a variant semiconductor photodiode and FIGS. 9A and 9B show cross-sectional views of the variant semiconductor photodiode of FIG. 8 along the lines A-A′ and B-B′ respectively. The variant shown in FIG. 8 differs from that shown in FIG. 1 in that the guard section is wider (around 1.1 μm) than in FIG. 1. This makes it easier for the metal to contact the sidewalls. The width tapers along an approximately 1 μm long region located between the photodiode region and the guard region. No degradation to responsivity or speed was noted, with both the resistances and complex capacitances being similar to those in FIG. 1. Advantageously, it is easier to fabricate the wider waveguide region (i.e. the guard section). The undoped region has the same width in both regions (i.e. in both the 9 μm long photodiode region and in the 15 μm long guard section) however the doped regions become wider. Both regions, in this example, have the same height of around 250 nm from the silicon-on-insulator layer.

The features disclosed in the description, or in the following claims, or in the accompanying drawings, expressed in their specific forms or in terms of a means for performing the disclosed function, or a method or process for obtaining the disclosed results, as appropriate, may, separately, or in any combination of such features, be utilised for realising the invention in diverse forms thereof.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

For the avoidance of any doubt, any theoretical explanations provided herein are provided for the purposes of improving the understanding of a reader. The inventors do not wish to be bound by any of these theoretical explanations.

Any section headings used herein are for organizational purposes only and are not to be construed as limiting the subject matter described.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

It must be noted that, as used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by the use of the antecedent “about,” it will be understood that the particular value forms another embodiment. The term “about” in relation to a numerical value is optional and means for example +/−10%.

List of Features

| | |
|---|---|
| 100, 200 | Semiconductor photodiode |
| 102 | Input waveguide |
| 104 | Photodiode waveguide |
| 106 | Photodiode electrode(s) |
| 108, 408 | Metal contact |
| 110, 410 | N doped region |
| 112, 412 | N++ doped region |
| 114, 414 | P doped region |
| 116, 416 | P++ doped region |
| 118 | Upper cladding layer |
| 300 | Insulator layer |
| 302 | Photoresist |
| 304a, b | Vias |
| 306 | Metal |
| 308 | Hard mask |
| 402 | Bulk region |
| 602 | Semiconductor seed layer |

1. A semiconductor photodiode, the semiconductor photodiode including:
an input waveguide, arranged to receive an optical signal at a first port and provide the optical signal from a second port;
a photodiode waveguide, arranged to receive the optical signal from the second port of the input waveguide, and at least partially convert the optical signal into an electrical signal; and
an electro-static defence component, located adjacent to the photodiode waveguide;
wherein the electro-static defence component and the photodiode waveguide are electrically connected in parallel.

2. The semiconductor photodiode of claim 1, wherein the photodiode waveguide and the electro-static defence component are electrically connected via a pair of electrodes, each electrode having a wider cross-section in a region adjacent to the electro-static defence component than a region adjacent to the photodiode waveguide.

3. The semiconductor photodiode of claim 1, wherein the photodiode waveguide and the electro-static defence component are electrically connected via a pair of doped regions of semiconductor, each doped region of semiconductor having a wider cross-section in a portion adjacent to the electro-static defence component than a portion adjacent to the photodiode waveguide.

4. The semiconductor photodiode of claim 1, wherein the photodiode waveguide includes first and second doped regions extending from a slab adjacent to the photodiode waveguide along respective sidewalls of the photodiode waveguide.

5. The semiconductor photodiode of claim 4, wherein:
the first and second doped regions of the photodiode waveguide each contain a first and second sub-region, the first sub-region of each doped region containing a higher concentration of dopants than the second sub-region of each doped region, and
wherein the first sub-regions of the first and second doped regions of the photodiode waveguide extend only along the slab adjacent to the photodiode waveguide.

6. The semiconductor photodiode of claim 5, wherein the electro-static defence component includes first and second doped regions extending from the slab adjacent to the photodiode waveguide up respective sidewalls of a waveguide within the electro-static defence component, which is coupled to the photodiode waveguide.

7. The semiconductor photodiode of claim 6, wherein:
the first and second doped regions of the electro-static defence component each contain a first and second sub-region, the first sub-region of each doped region containing a higher concentration of dopants than the second sub-region of each doped region, and
wherein the first and second sub-regions of the first and second doped regions of the electro-static defence component extend along a slab and also up respective sidewalls of the waveguide within the electro-static defence component.

8. The semiconductor photodiode of claim 1, wherein
the photodiode waveguide and the electro-static defence component each contain a P-I-N junction, and
wherein a width of the intrinsic region of the P-I-N junction within the electro-static defence component is smaller than a corresponding width of the intrinsic region of the P-I-N junction within the photodiode waveguide.

9. The semiconductor photodiode of claim 1, wherein the electro-static defence component is wider than the photodiode waveguide.

10. The semiconductor photodiode of claim 9, wherein the photodiode waveguide includes a tapered region, which tapers from a width of the photodiode waveguide to the width of the electro-static defence component.

11. The semiconductor photodiode of claim 10, wherein the electro-static defence component and the photodiode waveguide each comprise a doped region, and
wherein the doped region of the electro-static defence component is further from a substrate of the semiconductor photodiode than the doped region of the photodiode waveguide.

12. The semiconductor photodiode of claim 1, wherein the semiconductor photodiode further comprises a substrate, a device layer, and an insulator layer located between the substrate and the device layer, and wherein the photodiode waveguide and the electro-static defence component are each located on a same opposing side of the device layer to the insulator layer.

13. The semiconductor photodiode of claim 1, wherein the semiconductor photodiode further comprises a substrate, a device layer, and a semiconductor seed layer located between the substrate and the device layer, and wherein the photodiode waveguide and the electro-static defence component are each located on a same opposing side of the device layer to the semiconductor seed layer.

14. The semiconductor photodiode of claim 13, wherein the semiconductor seed layer is an epitaxial crystalline layer.

15. The semiconductor photodiode of claim 13, further comprising an insulator layer located on one or more lateral sides of the semiconductor seed layer.
